(19) United States
(12) Patent Application Publication
(10) Pub. No.: US 2006/0141691 A1
(43) Pub. Date: Jun. 29, 2006

(54) Method for fabricating semiconductor device

(76) Inventor: Jung-Nam Kim, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/284,565

(22) Filed: Nov. 21, 2005

(30) Foreign Application Priority Data
Dec. 28, 2004 (KR) 2004-0113989

(51) Int. Cl. H01L 21/336

(52) U.S. Cl. 438/199; 438/589; 438/270

(57) ABSTRACT

A method for fabricating a semiconductor memory device is provided. The method includes: forming a trench in a portion of a substrate, defined as a cell region; forming a first polysilicon layer doped with N-type impurities on regions where N-type metal-oxide-semiconductor (MOS) transistors are to be formed in the cell region and the periphery region; forming a second polysilicon layer doped with P-type impurities on an area where a P-type MOS transistor is to be formed; forming a gate metal layer over the first and the second polysilicon layers; forming a gate hard mask layer on the gate metal layer; and patterning the gate hard mask layer, the gate metal layer, and the first and the second polysilicon layers to form gate patterns for the N-type MOS transistors in the cell region and the periphery region, and the P-type MOS transistor in the periphery region.

### FIELD OF THE INVENTION

The present invention relates to a method for fabricating a semiconductor memory device; and, more particularly, to a method for fabricating a semiconductor memory device with metal-oxide-semiconductor (MOS) transistor gate patterns formed in buried type in a cell region to increase the length of channels.

### DESCRIPTION OF RELATED ARTS

As semiconductor devices have become highly integrated, the sizes of gate patterns in the semiconductor device have been scaled down due to the decreasing design rule of MOS transistors. Thus, the length of channels is shortened, causing a plurality of limitations.

Examples of suggested conventional methods to overcome the limitations include: slightly recessing a predetermined portion of a substrate on which source/drain regions are to be formed adjacent to the gate patterns on the substrate, so that the channels are lengthened artificially; and filling the gate patterns of the MOS transistors in the substrate to lengthen the channels.

FIGS. 1A to 1D are cross-sectional views illustrating a conventional method for fabricating a semiconductor device.

Referring to FIG. 1A, a periphery region ‘PERI’ and a cell region ‘CELL’ are defined in a substrate 10, and then, device isolation regions 11 are formed in the substrate 10.

Previously, the device isolation regions were formed through a local oxidation of silicon method. However, a shallow trench isolation (STI) method, advantageous for integration, is currently used for the device isolation region formation.

Subsequently, a trench 12 is formed in the cell region. The trench 12 is a region where a gate pattern for an N-type MOS transistor to be formed in the cell region is to be partially filled.

Next, a gate insulation layer 13 is formed over the trench 12.

Referring to FIG. 1B, a polysilicon layer 14 is formed over the gate insulation layer 13, filling the trench 12. Herein, the polysilicon layer 14 is in an undoped state.

Afterwards, a photoresist pattern 15 is formed, exposing predetermined portions of the polysilicon layer 14 on which the N-type MOS transistors are to be formed in the cell region and the periphery region. Then, N-type impurities are implanted using the photoresist pattern 15 as a mask.

However, the portions of the polysilicon layer disposed in the cell region and the periphery region are shaped differently. Thus, it is extremely difficult to obtain a desired doping concentration level in the cell region and the periphery region by implanting the N-type impurities at a fixed energy level.

Referring to FIG. 1C, the photoresist pattern 15 is removed, and another photoresist pattern 16 is formed, exposing a predetermined portion of the polysilicon layer 14 on which a P-type MOS transistor is to be formed.

Subsequently, P-type impurities are implanted using said another photoresist pattern 16 as a mask.

Referring to FIG. 1D, said another photoresist pattern 16 is removed, a gate metal layer 17 and a gate hard mask layer 18 are formed on the polysilicon layer 14 and then, patterned to form gate patterns.

Herein, ‘A’ refers to the gate pattern for the N-type MOS transistor in the cell region, ‘B’ refers to the gate pattern for the N-type MOS transistor in the periphery region, and ‘C’ refers to the gate pattern for the P-type MOS transistor in the periphery region.

The above-described conventional method forms the gate patterns on a semiconductor memory device through the steps of: forming the undoped polysilicon layer; and forming the gates of the N-type MOS transistors and the P-type MOS transistor through two rounds of the photolithography process and the ion implantation process using the two separate photoresist patterns.

Also, the N-type MOS transistors are formed in the cell region and the periphery region by implanting the N-type impurities in each of the regions as illustrated.

However, as described above, forming a recess channel array transistor (RCAT), the MOS transistors on the cell array with the gate patterns filled in the substrate, is unreliable in doping the N-type impurities in the cell region and the periphery region at the desired doping concentration level by a single round of the ion implantation process of the N-type impurities.

To overcome this limitation, each of the ion implantation processes for the gate patterns in the cell region and the periphery region should be performed separately. However, the process becomes extremely complicated due to the two separate rounds of the photolithography process and the ion implantation process.

### SUMMARY OF THE INVENTION

It is, therefore, an object of the present invention to provide a method for fabricating a semiconductor memory device capable of forming MOS transistors on a cell array with gate patterns filled in a substrate without an ion implantation process.

In accordance with an aspect of the present invention, there is provided a method of fabricating a semiconductor memory device, including: forming a trench in a portion of a substrate, defined as a cell region; forming a first polysilicon layer doped with N-type impurities on regions where N-type metal-oxide-semiconductor (MOS) transistors are to be formed in the cell region and the periphery region such that the first polysilicon layer fills the trench; forming a second polysilicon layer doped with P-type impurities on an area where a P-type MOS transistor is to be formed; forming a gate metal layer over the first polysilicon layer and the second polysilicon layer; forming a gate hard mask layer on the gate metal layer; and patterning the gate hard mask layer, the gate metal layer, and the first and the second polysilicon layers to form gate patterns for the N-type MOS transistors in the cell region and the periphery region, and the P-type MOS transistor in the periphery region.

### BRIEF DESCRIPTION OF THE DRAWINGS

The above and other objects and features of the present invention will become better understood with respect to the following description of the preferred embodiments given in conjunction with the accompanying drawings, in which:

FIGS. 1A to 1D are cross-sectional views illustrating a conventional method for fabricating a semiconductor device; and

FIGS. 2A to 2F are cross-sectional views illustrating a method for fabricating a semiconductor device in accordance with a specific embodiment of the present invention.

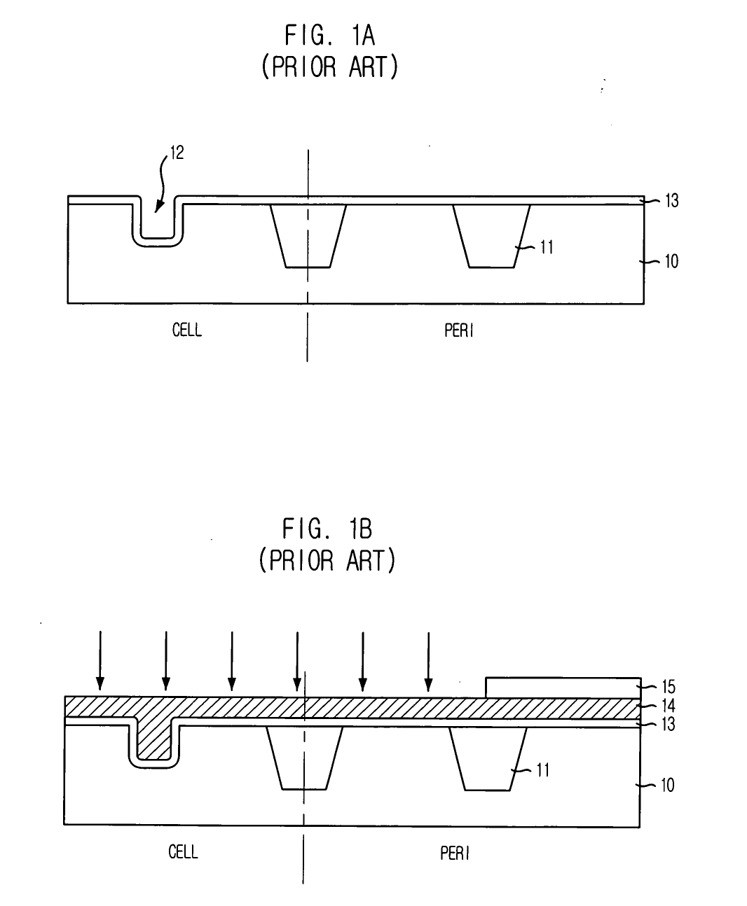

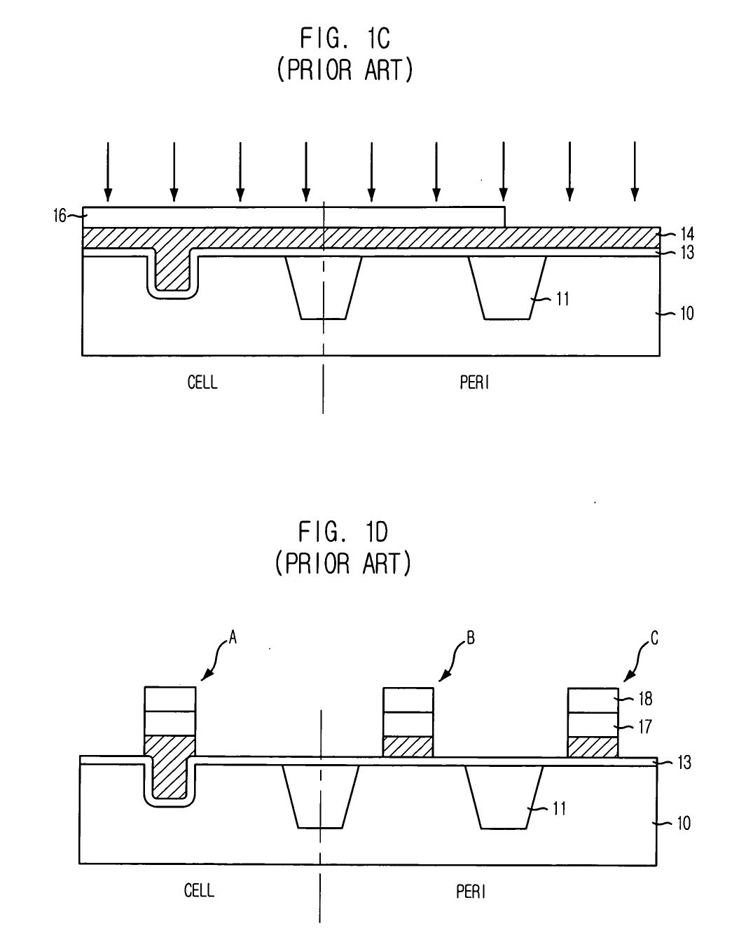

### DETAILED DESCRIPTION OF THE INVENTION

A method for fabricating a semiconductor device in accordance with a specific embodiment of the present invention will be described in detail with reference to the accompanying drawings, which is set forth hereinafter.

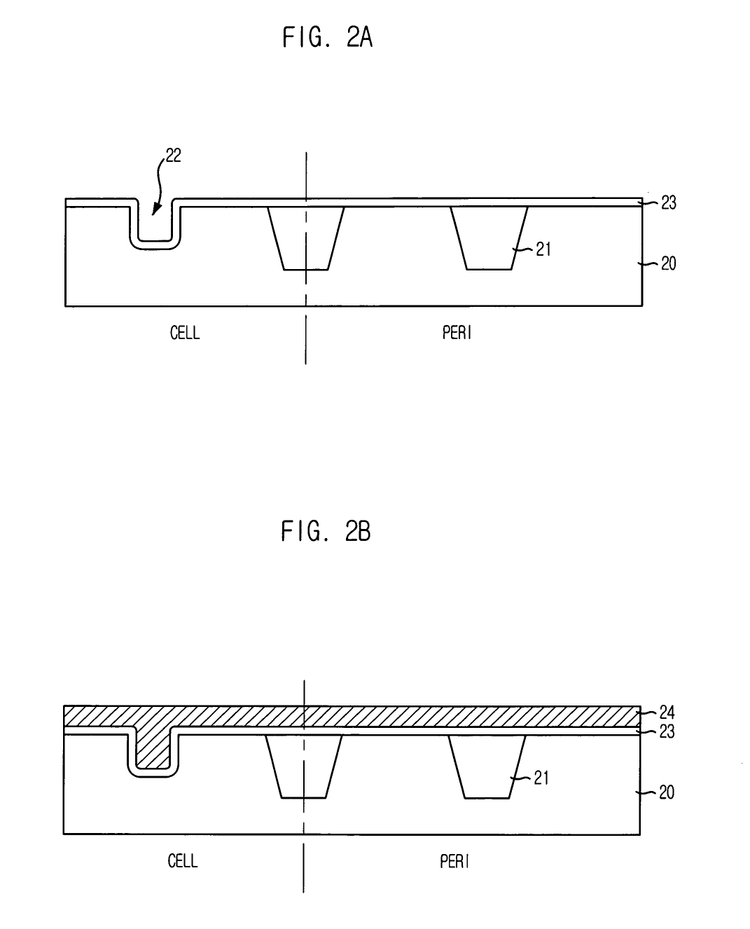

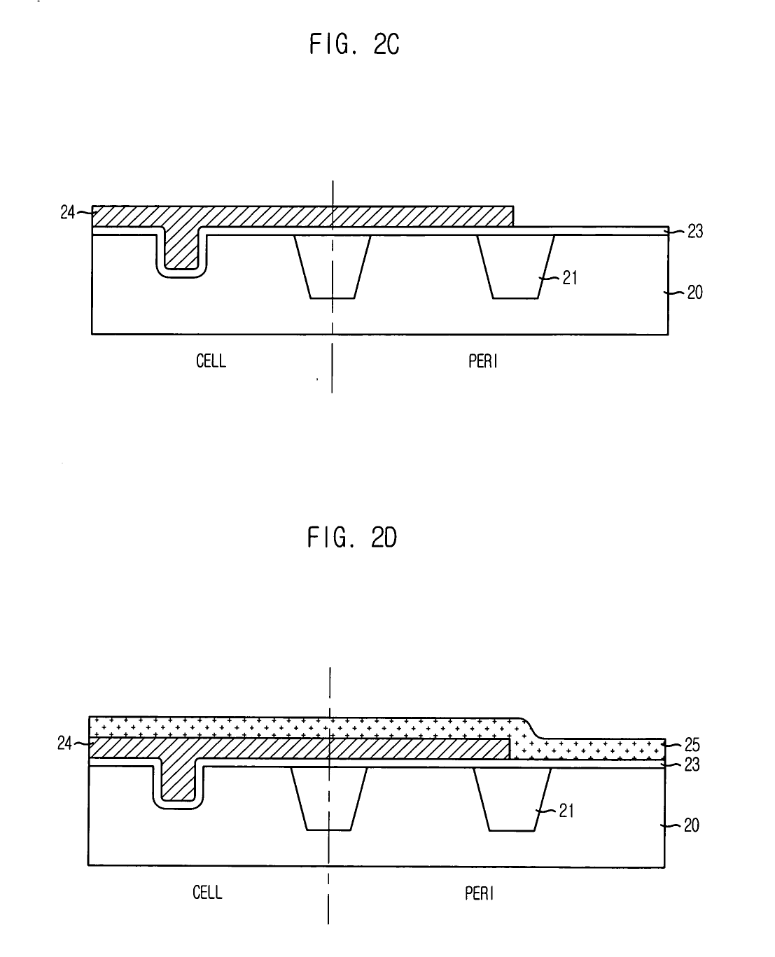

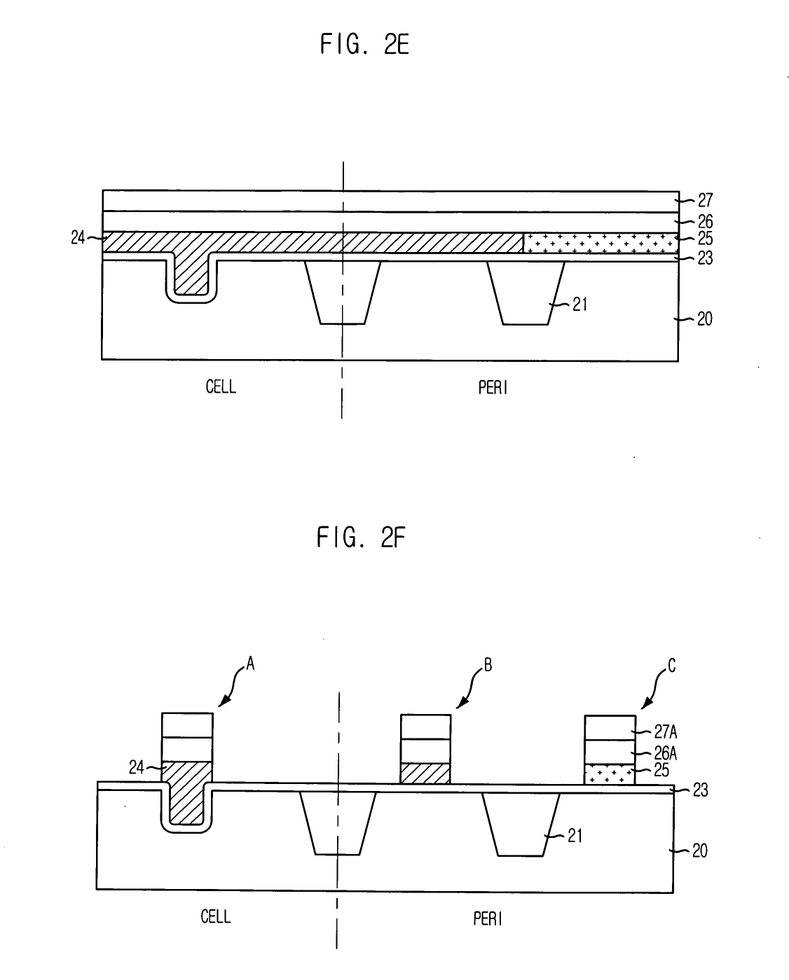

FIGS. 2A to 2F are cross-sectional views illustrating a method for fabricating a semiconductor device in accordance with one embodiment of the present invention.

Referring to FIG. 2A, a periphery region and a cell region are defined in a substrate 20, and then, device isolation regions 21 are formed on the substrate 20.

Subsequently, a trench 22 is formed in the cell region. The trench 22 is a region where a gate pattern for an N-type MOS transistor to be formed in the cell region is to be partially filled.

Next, a gate insulation layer 23 is formed over the trench 22. Herein, the gate insulation layer 23 is formed by utilizing a silicon oxide layer.

Referring to FIG. 2B, a first polysilicon layer 24, doped with N-type impurities, is formed over the gate insulation layer 23, filling the trench 22. Herein, arsenic (As) or phosphorus (P) is used as the N-type impurities. The first polysilicon layer 24 is formed in a thickness ranging from approximately 500 Å to approximately 1,000 Å at a temperature ranging from approximately 500° C. to approximately 600° C. by utilizing one gas selected from phosphine (PH₃) and arsine (AsH₃), silane (SiH₄) gas and nitrogen (N₂) gas at an approximate ratio of 8-12:1-3:1-3.

Referring to FIG. 2C, a predetermined portion of the first polysilicon layer 24 on which a P-type MOS transistor is to be formed, is removed in the periphery region. Herein, a predetermined portion of the first polysilicon layer 24 on which N-type MOS transistors are to be formed, is excluded from the removal process.

Referring to FIG. 2D, a second polysilicon layer 25, doped with P-type impurities, is formed over an entire surface of the above resulting structure in-situ. As illustrated, the second polysilicon layer 25 is formed over the remaining portion of the first polysilicon layer 24 doped with the N-type impurities. Also, boron (B) or boron difluoride (BF₂) is used as the P-type impurities. The second polysilicon layer 25 is formed in a thickness ranging from approximately 500 Å to approximately 1,000 Å at a temperature ranging from approximately 500° C. to approximately 600° C. by utilizing boron fluoride (BF₃) gas, silane (SiH₄) gas and nitrogen (N₂) gas at an approximate ratio of 8-12:1-3:1-3.

Referring to FIG. 2E, the second polysilicon layer 25 formed over the remaining portion of the first polysilicon layer 24 is planarized through a chemical mechanical polishing (CMP) process. That is, the CMP process planarizes the second polysilicon layer 25 until a surface of the first polysilicon layer 24 is exposed.

Next, a gate metal layer 26 and a gate hard mask layer 27 are formed on the above resulting planarized substrate structure. Herein, the gate hard mask layer 27 is formed by employing nitride-based silicon, and the gate metal layer 26 is formed by employing tungsten silicide. The gate hard mask layer 27 is formed in a thickness ranging from approximately 2,000 Å to approximately 2,500 Å at a temperature ranging from approximately 600° C. to approximately 800° C. utilizing N₂, ammonia (NH₃) and dichlorosilane (SiH₂Cl₂) gases. The gate metal layer 26 is formed in a thickness ranging from approximately 500 Å to approximately 1,500 Å utilizing tungsten hexafluoride (WF₆) and SiH₄ gases.

Referring to FIG. 2F, the gate hard mask layer 27, the gate metal layer 26, the first polysilicon layer 24, and the second polysilicon layer 25 are patterned to form gate patterns of the N-type MOS transistors in the cell region and the periphery region, and the P-type MOS transistor in the periphery region.

Herein, ‘A’ refers to the gate pattern for the N-type MOS transistor in the cell region, ‘B’ refers to the gate pattern for the N-type MOS transistor in the periphery region, and ‘C’ refers to the gate pattern for the P-type MOS transistor in the periphery region. Also, reference numerals 26A and 27A represent a patterned gate hard mask layer and a patterned gate metal layer, respectively.

As described in this specific embodiment of the present invention, the polysilicon layer used in the gate patterning process for the N-type MOS transistors in the cell region and the periphery region, is formed without an ion implantation process. Instead, the polysilicon layer doped with the N-type impurities is formed, and then patterned.

Thus, this embodiment overcomes the limitations of the conventional method with the unreliable ion implantation process due to the different shapes of the gate patterns for the N-type MOS transistors in the cell region and the periphery region.

In accordance with the specific embodiment of the present invention, the gate patterns are formed by forming the polysilicon layers doped with the N-type impurities and the P-type impurities in-situ, instead of the ion implantation method. As a result, the process of fabricating a semiconductor memory device may be simplified without a difficulty in controlling the ion implantation process when the gate pattern partially filled in the substrate is formed in the cell region.

The present application contains subject matter related to the Korean patent application No. KR 2004-113989, filed in the Korean Patent Office on Dec. 28, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a semiconductor memory device, comprising:
forming a trench in a portion of a substrate, defined as a cell region;
forming a gate oxide layer over the substrate including the trench;
forming a first polysilicon layer doped with N-type impurities on regions where N-type metal-oxide-semiconductor (MOS) transistors are to be formed in the cell region and the periphery region such that the first polysilicon layer fills the trench;
forming a second polysilicon layer doped with P-type impurities on an area where a P-type MOS transistor is to be formed;
forming a gate metal layer over the first polysilicon layer and the second polysilicon layer;
forming a gate hard mask layer on the gate metal layer; and
patterning the gate hard mask layer, the gate metal layer, and the first and the second polysilicon layers to form gate patterns for the N-type MOS transistors in the cell region and the periphery region, and the P-type MOS transistor in the periphery region.

2. The method of claim 1, wherein the forming of the second polysilicon layer includes:
forming the second polysilicon layer over the first polysilicon layer and the substrate; and
planarizing the second polysilicon layer by removing the second polysilicon layer formed over the first polysilicon layer, so that the first polysilicon layer remains in the cell region and the periphery region whereon the N-type MOS transistors are to be formed, and the second polysilicon layer remains in the periphery region whereon the P-type MOS transistor is to be formed.

3. The method of claim 2, wherein the N-type impurities include one of arsenic (As) and phosphorus (P).

4. The method of claim 2, wherein the first polysilicon layer is formed in a thickness ranging from approximately 500 Å to approximately 1,000 Å at a temperature ranging from approximately 500° C. to approximately 600° C. by utilizing one gas selected from phosphine (PH₃) and arsine (AsH₃), silane (SiH₄) gas and nitrogen (N₂) gas at an approximate ratio of 8-12:1-3:1-3.

5. The method of claim 2, wherein the P-type impurities include one of boron (B) and boron difluoride (BF₂).

6. The method of claim 2, wherein the second polysilicon layer is formed in a thickness ranging from approximately 500 Å to approximately 1,000 Å at a temperature ranging from approximately 500° C. to approximately 600° C. by utilizing boron trifluoride (BF₃) gas, silane (SiH₄) gas and nitrogen (N₂) gas at an approximate ratio of 8-12:1-3:1-3.

7. The method of claim 2, wherein the gate metal layer is formed by employing tungsten silicide.

8. The method of claim 2, wherein the gate metal layer is formed in a thickness ranging from approximately 500 Å to approximately 1,500 Å utilizing tungsten hexafluoride (WF₆) and SiH₄ gases.

9. The method of claim 2, wherein the gate hard mask layer is formed by employing nitride-based silicon.

10. The method of claim 2, wherein the gate hard mask layer is formed in a thickness ranging from approximately 2,000 Å to approximately 2,500 Å at a temperature ranging from approximately 600° C. to approximately 800° C. utilizing N₂, ammonia (NH₃) and dichlorosilane (SiH₂Cl₂) gases.
